(19) United States
(12) Patent Application Publication
(10) Pub. No.: US 2016/0013248 A1
(43) Pub. Date: Jan. 14, 2016

(54) PHOTOELECTRIC CONVERSION ELEMENT AND IMAGING DEVICE USING THE SAME

(71) Applicant: FUJIFILM Corporation, Tokyo (JP)

(72) Inventor: Daigo SAWAKI, Ashigarakami-gun (JP)

(73) Assignee: FUJIFILM Corporation, Tokyo (JP)

(21) Appl. No.: 14/865,990

(22) Filed: Sep. 25, 2015

Related U.S. Application Data
(63) Continuation of application No. PCT/JP2014/001825, filed on Mar. 28, 2014.

(30) Foreign Application Priority Data
Mar. 29, 2013 (JP) 2013-073885
Jan. 24, 2014 (JP) 2014-011366

(51) Int. Cl. H01L 27/30; H01L 51/42

(52) U.S. Cl. CPC H01L 27/307; H01L 51/4273; H01L 51/0046

(57) ABSTRACT

An organic photoelectric conversion element has a light receiving layer which includes at least a photoelectric conversion layer sandwiched between a hole collecting electrode and an electron collecting electrode, and an electron blocking layer is provided between the hole collecting electrode and the electron collecting electrode. The photoelectric conversion layer is formed of a first photoelectric conversion layer which is a bulk hetero layer of an n-type organic semiconductor and a p-type organic semiconductor, and a second photoelectric conversion layer formed in contact with the surface of the first photoelectric conversion layer on the hole collecting electrode side. The average value of the mixing ratio of the n-type organic semiconductor to the p-type organic semiconductor in the second organic semiconductor layer is higher than the average value in the photoelectric conversion layer formed of the first photoelectric conversion layer and the second photoelectric conversion layer.

### CROSS-REFERENCE TO RELATED APPLICATIONS

This application is a Continuation of PCT International Application No. PCT/JP2014/001825 filed on Mar. 28, 2014, which claims priority under 35 U.S.C. §119 (a) to Japanese Patent Application No. 2013-073885 filed on Mar. 29, 2013 and Japanese Patent Application No. 2014-011366 filed on Jan. 24, 2014. Each of the above applications is hereby expressly incorporated by reference, in its entirety, into the present application.

### BACKGROUND

The present disclosure relates to an organic photoelectric conversion element having a photoelectric conversion layer formed of an organic layer, and an imaging device equipped therewith.

Imaging devices, such as CCD sensors, CMOS sensors, and the like, are widely known as image sensors used in digital still cameras, digital video cameras, cell phone cameras, endoscope cameras, and the like. These devices are equipped with a photoelectric conversion element having a light receiving layer which includes a photoelectric conversion layer.

Development of photoelectric conversion elements that use organic compounds and imaging devices using the same has been conducted by the present applicant, et al. For the photoelectric conversion elements used in applications, such as the sensors and imaging devices described above, the S/N ratio of photocurrent/dark current, response speed, and photoelectric conversion efficiency (sensitivity) are important in their performance.

The present applicant, et al. filed a patent application for an organic photoelectric conversion element that uses a mixed layer (bulk hetero layer) of a p-type organic semiconductor and an n-type semiconductor, such as a fullerene, a fullerene derivative, or the like, in a portion of a light receiving layer, with a view to improve the photoelectric conversion efficiency (sensitivity) (Japanese Unexamined Patent Publication No. 2007-123707).

Further, the present applicant, et al. disclose, in Japanese Unexamined Patent Publication No. 2012-094660, a photoelectric conversion element in which at least one layer of an electron blocking layer is a mixed layer that includes a fullerene, in a configuration in which a bulk hetero layer is provided in a portion of a light receiving layer.

Japanese Unexamined Patent Publication No. 2012-004578 discloses a photoelectric conversion element in which generation of dark current is suppressed and photoelectric conversion efficiency is improved by reducing the mixing ratio of fullerene family to a p-type semiconductor less than or equal to 2:1 in a bulk hetero layer. Further, Japanese Unexamined Patent Publication No. 2009-099866 describes that at least a portion of a photoelectric conversion layer is a bulk hetero layer, and that the dark current is suppressed and the photoelectric conversion efficiency is increased by increasing the volume ratio of fullerene family in the bulk hetero layer on the electron collecting electrode side.

### SUMMARY

As the method of forming bulk hetero layers, a co-deposition method is often used, in which a p-type organic semiconductor material and an n-type organic semiconductor material are co-deposited. The co-deposition may form a film having an intended composition by disposing for example, two kinds of evaporation sources and controlling their evaporation amounts and speeds. In a case where bulk hetero layers are formed by co-deposition, the response speed and sensitivity of photoelectric conversion elements may differ depending on the deposition conditions. The film forming is generally controlled by opening and closing a shutter in co-deposition, the film composition to be formed may sometimes be changed according to the opening state of the shutter at the time of opening and closing the shutter. The change in film composition may sometimes have adverse impacts on the performance of the photoelectric conversion element, such as response speed, carrier transportability (sensitivity), heat resistance, and the like. Therefore, it is desirable that film forming be performed without being influenced by such adverse impacts as much as possible. The present disclosure has been developed in view of the circumstances described above, and the present disclosure provides an organic photoelectric conversion element which is excellent in response speed, carrier transportability (sensitivity), and heat resistance.

An organic photoelectric conversion element of the present disclosure is an organic photoelectric conversion element, including a light receiving layer which includes at least a photoelectric conversion layer sandwiched between a hole collecting electrode and an electron collecting electrode, wherein:

an electron blocking layer is provided between the hole collecting electrode and the electron collecting electrode;

the photoelectric conversion layer is formed of a first photoelectric conversion layer which is a bulk hetero layer of an n-type organic semiconductor and a p-type organic semiconductor, and a second photoelectric conversion layer formed in contact with the surface of the first photoelectric conversion layer on the hole collecting electrode side; and

the average value of the mixing ratio of the n-type organic semiconductor to the p-type organic semiconductor in the second organic semiconductor layer is higher than the average value in the photoelectric conversion layer formed of the first photoelectric conversion layer and the second photoelectric conversion layer.

The average value of the mixing ratio of the n-type organic semiconductor to the p-type organic semiconductor is the value obtained in the following manner. The absorption spectra of a p-type organic semiconductor single film and an n-type organic semiconductor single film are measured by spectral absorption measurement in advance to understand the correlation between the absobance and the film thickness of the absorption peak for each of the p-type and the n-type. Thereafter, the spectral absorption measurement is performed on the bulk hetero film, then the film thickness is calculated from the absorbance of the absorption peak of each of the p-type and n-type organic semiconductors, and a ratio between the p-type and the n-type in the bulk hetero is obtained. The p-type and n-type absorption peaks differ depending on the material and the absorption peak needs to be obtained for each material. In the present embodiment, compounds 1, 3, and 4 of the p-type organic semiconductor used in the photoelectric conversion layer have an absorption peak at 560 nm and a compound 5 has an absorption peak at 600 nm, while the n-type organic semiconductor has an absorption peak at 400 nm. In the present embodiment, the spectral absorption measurement is performed using UV3360 manufactured by HITACHI.

The thickness of the second organic semiconductor layer is preferably less than or equal to 0.75% of the thickness of the photoelectric conversion layer formed of the first photoelectric conversion layer and the second photoelectric conversion layer. The thickness of each layer refers to the average value of measurements, after each layer is formed, at four arbitrary points at an end portion of each film by stylus film thickness meter DEKTAK.

The present disclosure is suitable in a case where the hole collecting electrode is a lower electrode. The n-type organic semiconductor preferably includes a fullerene. The term “a fullerene” as used herein refers to “a fullerene and a fullerene derivative”. The p-type organic semiconductor preferably includes a compound represented by a general formula (1) below:

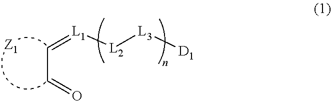

where, Z₁ represents a ring containing at least two carbon atoms and represents a fused ring containing at least one of five membered ring, a six membered ring, or five and six membered rings, L₁, L₂, and L₃ each independently represents an unsubstituted methine group or a substituted methine group, D₁ represents a group of atoms, and n represents an integer greater than or equal to 0.

An imaging device of the present disclosure includes a plurality of the photoelectric conversion elements of the present disclosure described above, and a circuit substrate in which is formed a signal readout circuit for reading out a signal according to a charge generated in the photoelectric conversion layer of each organic photoelectric conversion element.

The photoelectric conversion element of the present disclosure includes the photoelectric conversion layer formed of the first photoelectric conversion layer and the second photoelectric conversion layer, in which the second photoelectric conversion layer is formed on the surface of the first photoelectric conversion layer on the electron collecting electrode side and is composed such that the average value of the mixing ratio of the n-type organic semiconductor to the p-type organic semiconductor is higher than the average value in the photoelectric conversion layer formed of the first photoelectric conversion layer and the second photoelectric conversion layer. According to such composition, the decrease in mobility in the photoelectric conversion layer due to the presence of a single composition film of the p-type organic semiconductor or an area of a large composition of the p-type organic semiconductor at an end portion on the hole collecting electrode side, and recombination near the end portion may be suppressed. Therefore, the organic photoelectric conversion element of the present disclosure is excellent in response speed, carrier transportability (sensitivity), and heat resistance.

### BRIEF DESCRIPTION OF THE DRAWINGS

FIG. 1 is a schematic cross-sectional view of a photoelectric conversion element according to one embodiment of the present disclosure, schematically illustrating the configuration thereof.

FIG. 2 is a schematic cross-sectional view of an imaging device according to one embodiment of the present disclosure, schematically illustrating the configuration thereof.

### DETAILED DESCRIPTION OF THE PREFERRED EMBODIMENTS

### Photoelectric Conversion Element

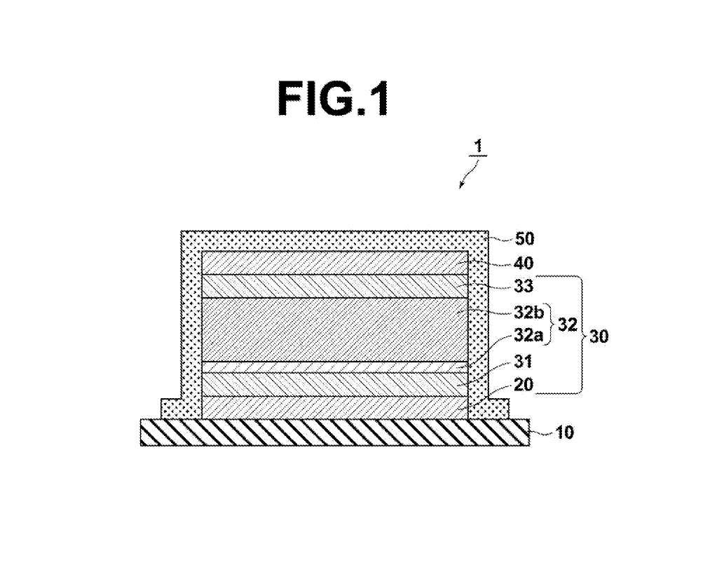

A photoelectric conversion element of one embodiment according to the present disclosure will be described with reference to the accompanying drawings. FIG. 1 is a schematic cross-sectional view of the photoelectric conversion element of the present embodiment, illustrating the configuration thereof. In the drawings herein, each component is not necessarily drawn to scale for ease of visual recognition.

As illustrated in FIG. 1, an organic photoelectric conversion element 1 (photoelectric conversion element 1) includes a substrate 10, a hole collecting electrode 20 formed on the substrate 10, an electron blocking layer 31 formed on the hole collecting electrode 20, a photoelectric conversion layer 32 formed on the electron blocking layer 31, a hole blocking layer 33 formed on the photoelectric conversion layer 32, an electron collecting electrode 40 formed on the hole blocking layer 33, and a sealing layer 50 covering the surface of the electron collecting electrode 40 and the sides of the layered body of the hole collecting electrode 20 to the electron collecting electrode 40.

In the photoelectric conversion element 1, the electron collecting electrode 40 is a transparent electrode, and when light is incident on the electron collecting electrode 40 from above, the light transmits to the electron collecting electrode 40 and incident on the photoelectric conversion layer 32, whereby charges are generated therein. Holes of the generated charges move to the hole collecting electrode 20 while electrons move to the electron collecting electrode 40.

The holes of the charges generated in the photoelectric conversion layer 32 may be moved to the hole collecting electrode 20 while the electrons may be moved to the electron collecting electrode 40 by applying a bias voltage (external electric field) between the electron collecting electrode 40 and the hole collecting electrode 20.

The photoelectric conversion layer 32 is formed of a first photoelectric conversion layer 32b on the electron collecting electrode 40 side and a second photoelectric conversion layer 32a on the hole collecting electrode side. The first photoelectric conversion layer 32b and the second photoelectric conversion layer 32a are bulk hetero layers, but the second photoelectric conversion layer 32a may be a single layer of an n-type organic semiconductor.

The photoelectric conversion layer formed of a bulk hetero layer may be optimized in (1) carrier transportability within the bulk hetero layer, (2) visible light absorption rate, (3) carrier transportability to the electron blocking layer, and (4) heat resistance Improving these properties will result in a heat resistant photoelectric conversion element which is excellent in response time and sensitivity with a reduced dark current.

(1) From the view point of carrier transportability within the bulk hetero layer, the content rate of the n-type organic semiconductor in the bulk hetero layer is preferably 40% to 80%.

(2) From the viewpoint of visible light absorption rate, if the amount of p-type organic semiconductor having an absorption peak wavelength in the visible region is small, the amount of absorption of incident light is reduced. Therefore, it is necessary to sufficiently mix the p-type organic semiconductor in the bulk hetero layer to obtain a sufficient absorption amount of incident light.

In a case of a high content rate of n-type organic semiconductor in the bulk hetero layer, if p-type organic semiconductor is sufficiently mixed, the thickness of the photoelectric conversion layer is increased. Although the photoelectric conversion element 1 may be driven by applying an external electric field between a pair of electrodes, if the film thickness of the photoelectric conversion layer 32 is increased, the voltage required to drive the photoelectric conversion element is increased. Therefore, the film thickness of the photoelectric conversion layer 32 is preferable to be as thin as possible. The film thickness of the photoelectric conversion layer 32 is preferably less than or equal to 1000 nm, more preferably less than or equal to 700 nm, and particularly preferably less than or equal to 500 nm. Therefore, the content rate of the n-type organic semiconductor in the photoelectric conversion layer 32 is preferably reduced as much as possible to sufficiently mix the p-type semiconductor for increasing visible light absorption.

(3) From the viewpoint of carrier transportability (hole transportability) to the electron blocking layer, holes of optical carriers generated in the photoelectric conversion layer 32 are collected by the hole collecting electrode 20 via the electron blocking layer 31.

It is considered that, if a mixed region of the organic semiconductor constituting the electron blocking layer 31 and the p-type organic semiconductor in the second photoelectric conversion layer 32a is formed at the contact interface between the electron blocking layer 31 and the second photoelectric conversion layer 32a, traps are formed in the mixed region, thereby causing degradation in sensitivity, photoelectric conversion efficiency, and dark current characteristics. Therefore, the photoelectric conversion layer on the electron blocking layer 31 side, that is, the photoelectric conversion layer in contact with the hole collecting electrode side preferably includes the p-type organic semiconductor as less as possible.

(4) From the viewpoint of heat resistance, when used for an optical sensor, processes of color filter forming, wire bonding, and the like are required to integrate into a device. As the imaging device is heated to higher than or equal to 200° C. during these processes, the organic photoelectric conversion film used in the imaging device needs to have a heat resistance of higher than or equal to 200° C.

The film of the bulk hetero layer is stabilized and heat resistance is improved with the increase in the content rate of the n-type semiconductor. Therefore, the content rate of the n-type organic semiconductor in the first photoelectric conversion layer 32b is preferably greater than or equal to 50% to realize a sufficiently high heat resistance. For the content of the n-type organic semiconductor in the second photoelectric layer 32a, the more the better, from the viewpoint of heat resistance.

According to the studies based on the viewpoints of (1) to (4) described above, for the content rate of the n-type organic semiconductor in the bulk hetero layer, the higher the better, in the viewpoints of response speed, carrier transportability, and heat resistance, while in the viewpoint of visible light absorption rate, it is better to suppress an increase in the film thickness of the bulk hetero layer by reducing the content rate of the n-type organic semiconductor. As a result of intensive studies, the present inventor has found out that the formation of traps described in (3) influences largely on the response speed, carrier transportability (sensitivity), and heat resistance (refer to examples to be described later).

In the viewpoint of (3), the content of the p-type organic semiconductor in the photoelectric conversion layer (bulk hetero layer) in contact with the electron blocking layer 31 side (hole collecting electrode side) is preferably as small as possible, and, in theory, the foregoing photoelectric conversion layer is preferably composed of only the n-type semiconductor (not a bulk hetero layer but a single layer). Hence, the present inventor has studied the composition and the film thickness of the second photoelectric conversion layer 32a on the hole collecting electrode side that may minimize the influence on the response speed, carrier transportability (sensitivity), and heat resistance.

Normally, too large difference in content rate of the n-type organic semiconductor between adjacent bulk hetero layers (photoelectric conversion layers) causes the interlayer carrier transport speed to be reduced, thereby causing reduction in the response speed of the photoelectric conversion element. The present inventor has found out that, even in a case where the second photoelectric conversion layer is formed as a single layer of the n-type organic semiconductor, the organic photoelectric conversion element may be an organic photoelectric conversion element that suppresses traps on the hole collecting electrode 20 side (electron blocking layer side) and has favorable response speed, carrier transportability (sensitivity), and heat resistance, without influencing largely on the interlayer carrier transport speed described above, by setting the thickness of the second photoelectric conversion layer 32a less than or equal to 0.75% of the thickness of the photoelectric conversion layer 32 formed of the first photoelectric conversion layer and the second photoelectric conversion layer, whereby the present disclosure has been completed.

That is, an organic photoelectric conversion element 1 includes a light receiving layer 30 which includes at least a photoelectric conversion layer 32 sandwiched between a hole collecting electrode 20 and an electron collecting electrode 40, in which:

an electron blocking layer 31 is provided between the hole collecting electrode 20 and the photoelectric conversion layer 32;

the photoelectric conversion layer 32 is formed of a first photoelectric conversion layer 32 which is a bulk hetero layer of an n-type organic semiconductor and a p-type organic semiconductor, and a second photoelectric conversion layer 32a formed in contact with the surface of the first photoelectric conversion layer 32b on the hole collecting electrode 20 side, and

the average value X2 of the mixing ratio of the n-type organic semiconductor to the p-type organic semiconductor in the second photoelectric conversion layer 32a is higher than the average value X1 in the photoelectric conversion layer formed of the first photoelectric conversion layer 32b and the second photoelectric conversion layer 32a. Hereinafter, the configuration of each layer of the organic photoelectric conversion element 1 will be described.

### Substrate and Electrodes

There is not any specific restriction on the substrate 10, and a silicon substrate, a glass substrate, and the like may be used. The hole collecting electrode 20 is an electrode for collecting holes of the charges generated in the photoelectric conversion layer 32, and corresponds to a pixel electrode in the configuration of an imaging device, to be described later. There is not any specific restriction on the material of the hole collecting electrode 20 as long as it has good conductivity, but sometimes it is given a transparency and other times a material that reflects light is used without giving transparency, depending on the application.

Specific materials include metals, metal oxides, metal nitrides, metal borides, organic conductive compounds, mixtures thereof, and the like. More specific examples include conductive metal oxides, such as tin oxides doped with antimony or fluorine (ATO, FTO), tin oxides, zinc oxides, indium oxides, indium tin oxide (ITO), indium zinc oxides (IZO), and the like; metals, such as gold, silver, chrome, nickel, titanium, tungsten, aluminum, and the like; conductive compounds, such as oxides and nitrides of these metals (titanium nitride (TiN) by way of example); mixtures or layered body of these metals and conductive metal oxides; inorganic conductive substances, such as copper iodide, copper sulfide, and the like; organic conductive materials, such as polyaniline, polythiophene and polypyrrole; and layered bodies of these and ITO or titanium nitride. Particularly preferable as the hole collecting electrode 20 is one of the materials of titanium nitride, molybdenum nitride, tantalum nitride, and tungsten nitride.

The electron collecting electrode 40 is an electrode for collecting electrons of the charges generated in the photoelectric conversion layer 32, and is the transparent electrode disposed on the light receiving side in the present embodiment. There is not any specific restriction on the material of the electron collecting electrode 40 as long as it is a conductive material which is sufficiently transparent to light having wavelengths to which the photoelectric conversion layer 32 has sensitivity, but the use of a transparent conductive oxide (TCO) is preferable in order to increase the absolute amount of light incident on the photoelectric conversion layer 32 and external quantum efficiency. The electron collecting electrode 40 corresponds to the opposite electrode in the configuration of an imaging device, to be described later.

As for the electron collecting electrode 40, one of the materials of ITO, IZO, SnO₂, ATO (antimony-doped tin oxide), ZnO, AZO (Al-doped zinc oxide), GZO (gallium-doped zinc oxide), TiO₂, FTO (fluorine-doped tin oxide) may be cited.

The light transmission rate of the electron collecting electrode 40 is preferably greater than or equal to 60%, more preferably greater than or equal to 80%, more preferably greater than or equal to 90%, and more preferably greater than or equal to 95% in the visible light wavelengths.

There is not any specific restriction on the method of forming the electrodes (20, 40) and may be selected appropriately by considering the suitability for the electrode material. More specifically, the electrodes may be formed by wet methods, such as printing, coating, and the like, physical methods, such as vacuum deposition, sputtering, ion plating, and the like, chemical methods, such as CVD, plasma CVD, and the like, and others.

If the electrode material is ITO, the electrodes may be formed by electron beam method, sputtering method, resistance heating deposition method, chemical reaction method (such as sol-gel method), method of coating a dispersion of indium tin oxide. Further, a UV-ozone treatment, a plasma treatment, and the like may be performed on the film formed of ITO. If the electrode material is TiN, various methods, including the reactive sputtering method, may be used and annealing, a UV-ozone treatment, a plasma treatment, and the like may be performed thereon.

If a transparent conductive film, such as TCO, is used as the electron collecting electrode 40, a DC short circuit or an increase in leak current may sometimes occur.

One of the causes for this is considered that the fine cracks introduced into the photoelectric conversion layer 32 are covered by a dense film, such as TCO, and the conduction to the hole collecting electrode 20 on the opposite side is increased. Therefore, in the case of an electrode having a relatively poor film quality, the increase in leak current is less likely to occur. By controlling the film thickness of the electron collecting electrode 40 with respect to the film thickness of the photoelectric conversion layer 32 (that is, crack depth), the increase in leak current may be suppressed largely. Preferably, the thickness of the electron collecting electrode 40 is less than or equal to ⅕ of the thickness of the photoelectric conversion layer 32, and more preferably less than or equal to 1/10.

Generally, if a conductive film is made thinner than a certain range, the resistance value increases rapidly, but in a solid-state imaging device that incorporates the photoelectric conversion element according to the present embodiment, the sheet resistance may preferably be 100 to 10000Ω/□, and has a large freedom of film thickness range in which the film thickness can be reduced. Further, the thinner the thickness of the electron collecting electrode 40, the less amount of light is absorbed thereby, and light transmission rate is generally increased. The increase in the light transmission rate is very desirable as it increases light absorption in the photoelectric conversion layer 32 and photoelectric conversion capability. The film thickness of the electron collecting electrode 40 is preferably 5 to 100 nm and more preferably 5 to 20 nm in view of the suppression of leak current, the resistance value increase in a thin film, and the transmission rate increase.

### Light Receiving Layer

The light receiving layer 30 is a layer that includes at least the electron blocking layer 31, the photoelectric conversion layer 32, and the already described hole blocking layer. There is not any specific restriction on the film forming method of the light receiving layer 30, and it may be formed by each of dry film forming methods or wet film forming methods. But, it is preferable that all the process steps are performed in a vacuum during the film forming, and basically it is preferable that the compound is prevented from directly contacting the oxygen and moisture in the ambient air. Such film forming method may be a vacuum deposition method. In the vacuum deposition method, it is preferable that the deposition speed is PI or PID controlled using a film thickness monitor, such as a crystal oscillator, an interferometer, and the like. Further, if two or more kinds of compounds are deposited simultaneously, a co-deposition method may be used, and it is preferable that the co-deposition method is performed using resistance heating evaporation, electron beam evaporation, flash evaporation, and the like.

If the light receiving layer 30 is formed by a dry film forming method, the degree of vacuum during the formation is preferably less than or equal to 1×10⁻³ Pa, more preferably less than or equal to 4×10⁻⁴ Pa, and particularly preferably less than or equal to 1×10⁻⁴ Pa, in view of preventing degradation in element characteristics during the formation of the light receiving layer.

The thickness of the light receiving layer 30 is preferably 10 nm to 1000 nm, further preferably 50 nm to 800 nm, and particularly preferably 100 nm to 600 nm The thickness of greater than or equal to 10 nm may provide a favorable dark current suppression effect while the thickness of less than or equal to 1000 nm may provide a favorable photoelectric conversion efficiency (sensitivity).

### Photoelectric Conversion Layer

As described above, the photoelectric conversion layer 32 is formed of the first photoelectric conversion layer 32b and the second photoelectric conversion layer 32a. As described above, the mixing ratio of the n-type organic semiconductor to the p-type organic semiconductor in the first photoelectric conversion layer 32b is preferably an optimized mixing ratio in consideration of carrier transportability, visible light absorption rate, and the like. The first photoelectric conversion layer 32b may be formed of one layer having a substantially uniform mixing ratio or a plurality of layers having different mixing ratios.

The second photoelectric conversion layer 32a may be any layer as long as it has the average value X2 of mixing ratio which is greater than the average value X1 of mixing ratio of the photoelectric conversion layer 32 formed of the first photoelectric conversion layer 32b and the second photoelectric conversion layer 32a, and may be a layer composed of only the n-type semiconductor. As the mixing ratio of the second photoelectric conversion layer 32a is greater than the optimized mixing ratio of the first photoelectric conversion layer 32b, the average film thickness of the second photoelectric conversion layer 32a is preferably as thin as possible and the thickness is preferably less than or equal to 0.75% of the average film thickness of the first photoelectric conversion layer 32b at most (refer to Examples described later).

There is not any specific restriction on the n-type organic semiconductor in the photoelectric conversion layer (bulk hetero layer) 32, and may include fullerene C₆₀, fullerene C₇₀, fullerene C₇₆, fullerene C₇₈, fullerene C₈₀, fullerene C₈₂, fullerene C₈₄, fullerene C₉, fullerene C₉₆, fullerene C₂₄₀, fullerene C₅₄₀, mixed-fullerene, fullerene nanotubes, and the like. The skeleton of a typical fullerene is shown below.

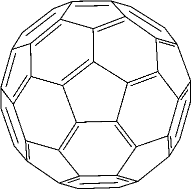 [SMILES: c1cc2c3ccc4c5ccc6c7ccc8c9ccc%10c1c1c2c2c3c4c3c5c6c4c7c8c5c9c%10c1c1c2c3c4c51]

The fullerene derivative refers to compounds obtained by adding substituent groups to those fullerenes. Preferable substituent groups of the fullerene derivatives may be alkyl group, aryl group, or heterocyclic group. An alkyl group having 1 to 12 carbon atoms is more preferable as the alkyl group. As the aryl group and the heterocyclic group, benzene ring, naphthalene ring, anthracene ring, phenanthrene ring, fluorene ring, triphenylene ring, naphthacene ring, biphenyl ring, pyrrole ring, furan ring, thiophene ring, imidazole ring, oxazole ring, thiazole ring, pyridine ring, pyrazine ring, pyrimidine ring, pyridazine ring, indolizine ring, indole ring, benzofuran ring, benzothiophene ring, isobenzofuran ring, benzimidazole ring, imidazopyridine ring, quinolizine ring, quinoline ring, phthalazine ring, naphthyridine ring, quinoxaline ring, quinoxazoline ring, isoquinoline ring, carbazole ring, phenanthridine ring, acridine ring, phenanthroline ring, thianthrene ring, chromene ring, xanthene ring, phenoxathiin ring, phenothiazine ring, or phenazine ring is preferable. Here, benzene ring, naphthalene ring, anthracene ring, phenanthrene ring, pyridine ring, imidazole ring, oxazole ring, or thiazole ring is more preferable, and benzene ring, naphthalene ring, or pyridine ring is particularly preferable. These may further have a substituent group and the substituent may be coupled as far as possible to form a ring. They may have a plurality of substituent groups which may be identical or different. Further, the plurality of substituent groups may be coupled as far as possible to form a ring.

In the bulk hetero layer 32, there is not any specific restriction on the p-type organic semiconductor mixed with the n-type organic semiconductor, but the absorption spectrum peak wavelength is preferably 450 nm to 700 nm, more preferably 480 nm to 700 nm, and further preferably 510 nm to 680 nm from the viewpoint of broadly absorbing light in the visible region. From the viewpoint of efficiently utilizing light, a higher molar absorption coefficient is more preferable. In the absorption spectrum (chloroform solution) is in the visible region of wavelengths 400 nm to 700 nm, the molar absorption coefficient is preferably is greater than or equal to 20000M⁻¹ cm⁻¹, more preferably greater than or equal to 30000M⁻¹ cm⁻¹, and further preferably greater than or equal to 40000M⁻¹ cm⁻¹.

The p-type organic semiconductor is a donor organic semiconductor (compound) mainly represented by a hole transport organic compound and is an organic compound having properties to easily donate electrons, and more specifically, when two organic materials are used in contact with each other, an organic compound having an ionization potential smaller than that of the other. Therefore, any organic compound may be used as the donor organic compound as long as it has electron donating properties.

As for the p-type organic semiconductor, for example, triarylamine compounds, pyran compounds, quinacridone compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, condensed aromatic carbocyclic compounds (naphthalene derivatives, anthracene derivatives, phenanthrene derivatives, tetracene derivatives, pyrene derivatives, perylene derivatives, fluoranthene derivative) and metal complexes having a nitrogen-containing heterocyclic compound as a ligand may be used, in which triarylamine compounds, pyran compounds, quinacridone compounds, pyrrole compounds, phthalocyanine compounds, merocyanine compounds, and condensed aromatic carbocyclic compounds are preferable.

An example suitable material for the p-type semiconductor is a compound represented by a general formula (1) below.

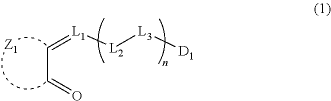

(where, Z₁ represents a group of atoms necessary to form a five or a six membered ring, L₁, L₂, and L₃ each independently represents an unsubstituted methine group or a substituted methine group, D₁ represents a group of atoms, and n represents an integer greater than or equal to 0.)

In the general formula (1), Z₁ is a ring containing at least two carbon atoms and represents a condensed ring containing at least any one of a five membered ring, a six membered ring, or a five and six membered ring. As the condensed ring containing at least any one of a five membered ring, a six membered ring, or a five and six membered ring, generally, a merocyanine dye used as an acidic nucleus is preferably used, specific examples of which are listed in the following.

(a) 1,3-dicarbonyl nucleus: for example, 1,3-indandione nucleus, 1,3-cyclohexanedione, 5,5-dimethyl-1,3-cyclohexanedione, 1,3-dioxane-4,6-dione, and the like.

(b) pyrazolinone nucleus: for example, 1-phenyl-2-pyrazoline-5-one, 3-methyl-1-phenyl-2-pyrazoline-5-one, 1-(2-benzothiazoyl)-3-methyl-2-pyrazoline-5-one, and the like.

(c) isoxazolinone nucleus: for example, 3-phenyl-2-isoxazoline-5-one, 3-methyl-2-isoxazoline-5-one, and the like.

(d) oxyindole nucleus: for example, 1-alkyl-2,3-dihydro-2-oxyindole, and the like.

(e) 2,4,6-triketohexahydropyrimidine nucleus: for example, barbituric acid or 2-thiobarbituric acid and derivatives thereof. Examples of the derivatives may include: a 1-alkyl derivatives, such as 1-methyl, 1-ethyl and the like; 1,3-dialkyl derivatives, such as 1,3-dimethyl, 1,3-diethyl, 1,3-dibutyl and the like; 1,3-diaryl derivatives, such as 1,3-diphenyl, 1,3-di(p-chlorophenyl), 1,3-di(p-ethoxycarbonylphenyl), and the like; 1-alkyl-1-aryl derivatives, such as 1-ethyl-3-phenyl and the like; 1,3-diheterocyclic-substituted derivatives, such as 1,3-di(2-pyridyl) and the like; and the like.

(f) 2-thio-2,4-thiazolidinedione nucleus: for example, laudanine, derivatives thereof and the like. Examples of the derivatives may include: 3-alkyllaudanine, such as 3-methyllaudanine, 3-ethyllaudanine, 3-allyllaudanine, and the like; 3-aryllaudanine, such as 3-phenyllaudanine, and the like; 3-heterocyclic-substituted laudanine, such as 3-(2-pyridyl) laudanine and the like; and the like.

(g) 2-thio-2,4-oxazolidinedione (2-thio-2,4-(3H,5H)-oxazoledione) nucleus: for example, 3-ethyl-2-thio-2,4-oxazolidinedione, and the like.

(h) thianaphthenone nucleus: for example, 3(2H)-thianaphthenone-1,1-dioxide, and the like.

(i) 2-thio-2,5-thiazolidinedione nucleus: for example, 3-ethyl-2-thio-2,5-thiazolidinedione, and the like.

(j) 2,4-thiazolidinedione nucleus: for example, 2,4-thiazolidinedione, 3-ethyl-2,4-thiazolidinedione, 3-phenyl-2,4-thiazolidinedione, and the like.

(k) thiazoline-4-one nucleus: for example, 4-thiazolidone, 2-ethyl-4-thiazolinone, and the like.

(l) 2,4-imidazolidinedione (hidantoin) nucleus: for example, 2,4-imidazolidinedione, 3-ethyl-2,4-imidazolidinedione, and the like.

(m) 2-thio-2,4-imidazolidinedione (2-thiohidantoin) nucleus: for example, 2-thio-2,4-imidazolidinedione, 3-ethyl-2-thio-2,4-imidazolidinedione, and the like.

(n) 2-imidazoline-5-one nucleus: for example, 2-propylmercapto-2-imidazoline-5-one, and the like.

(o) 3,5-pyrazolidinedione nucleus: for example, 1,2-diphenyl-3,5-pyrazolidinedione, 1,2-dimethyl-3,5-pyrazolidinedione, and the like.

(p) benzothiophene-3-one nucleus: for example, benzothiophene-3-one, oxobenzothiophene-3-one, dioxobenzothiophene-3-one, and the like. (q) indanone nucleus: for example, 1-indanone, 3-phenyl-1-indanone, 3-methyl-1-indanone, 3,3-diphenyl-1-indanone, 3,3-dimethyl-1-indanone, 3-dicyanomethylene-1-indanone, and the like.

Preferable rings represented by Z₁ include 1,3-dicarbonyl nucleus, pyrazolinone nucleus, 2,4,6-triketohexahydropyrimidine nucleus (including thioketone derivatives, for example, barbituric acid nucleus, 2-thiobarbituric acid nucleus), 2-thio-2,4-thiazolidinedione nucleus, 2-thio-2,4-oxazolidinedione nucleus, 2-thio-2,5-thiazolidinedione nucleus, 2,4-thiazolidinedione nucleus, 2,4-imidazolidinedione nucleus, 2-thio-2,4-imidazolidinedione nucleus, 2-imidazoline-5-one nucleus, 3,5-pyrazolidinedione nucleus, benzothiophene-3-one nucleus, and indanone nucleus, more preferable rings include 1,3-dicarbonyl nucleus, 2,4,6-triketohexahydropyrimidine nucleus (including thioketone derivatives, for example, barbituric acid nucleus, 2-thiobarbituric acid nucleus), 3,5-pyrazolidinedione nucleus, benzothiophene-3-one nucleus, and indanone nucleus, further preferable rings include 1,3-dicarbonyl nucleus, and 2,4,6-triketohexahydropyrimidine nucleus (including thioketone derivatives, for example, barbituric acid nucleus, 2-thiobarbituric acid nucleus), and particularly preferable rings include 1,3indanone nucleus, barbituric acid nucleus, 2-thiobarbituric acid nucleus, and derivatives thereof.

In the general formula (1), L₁, L₂, and L₃ each independently represents an unsubstituted methine group or a substituted methine group. Substituted methine groups may be bonded to form a ring. An example ring may be a six membered ring (e.g., benzene ring). An example substituent of the substituted methine group may be substituent W, to be described later. But a preferable case is that L₁, L₂, and L₃ are all unsubstituted methine groups.

In the general formula (1), n represents an integer greater than or equal to 0, preferably represents an integer of 0 to 3, and more preferably represents 0. An increase in n may make the absorption wavelength region longer wavelengths, but the thermal decomposition temperature is decreased. In terms of having appropriate absorption in the visible region and suppressing thermal decomposition during film deposition, n=0 is preferable.

In the general formula (1), Di represents a group of atoms. D₁ is preferably a group containing —NRa (Rb), and a preferable case is that D₁ represents an aryl group (preferably, a phenyl group or a naphthyl group which may have a substituent) in which —NRa (Rb) is substituted. Ra and Rb each independently represents a hydrogen atom or a substituent, and as the substituent, substituent W, to be described later, may be cited, but an aliphatic hydrocarbon group (preferably, an alkyl group or an alkenyl group which may have a substituent), an aryl group, or a heterocyclic group is preferable.

The arylene group represented by Di is preferably an arylene group having 6 to 30 carbon atoms, and more preferably an arylene group having 6 to 18 carbon atoms. The arylene group may have substituent W, to be described later, and preferably an arylene group having 6 to 18 carbon atoms, which may have an alkyl group having 1 to 4 carbon atoms. Examples thereof may include a phenylene group, a naphthylene group, an anthracenylene group, a pyrenylene group, a phenanthrenylene group, a methylphenylene group, a dimethylphenylene group and the like, and a phenylene group or a naphthylene group is preferable.

As the substituent represented by Ra and Rb may be the substituent W, to be described later, and an aliphatic hydrocarbon group (preferably an alkyl group, or an alkenyl group, which may be substituted), an aryl group (preferably a phenyl group which may be substituted), or a heterocyclic group.

Each of the aryl groups represented by Ra and Rb, independently preferably an aryl group having 6 to 30 carbon atoms and more preferably an aryl group having 6 to 18 carbon atoms. The aryl group may have a substituent, and is preferably an aryl group having 6 to 18 carbon atoms, which may have an alkyl group having 1 to 4 carbon atoms or an aryl group having 6 to 18 carbon atoms. Examples thereof include a phenyl group, a naphthyl group, an anthracenyl group, a pyrenyl group, a phenanthrenyl group, a methylphenyl group, a dimethylphenyl group, a biphenyl group, and the like, and a phenyl group or a naphthyl group is preferable.

Each of the heterocyclic groups represented by Ra and Rb is independently preferably a heterocyclic group having 3 to 30 carbon atoms and more preferably a heterocyclic group having 3 to 18 carbon atoms. The heterocyclic group may have a substituent, and is preferably a heterocyclic group having 3 to 18 carbon atoms, which may have an alkyl group having 1 to 4 carbon atoms or an aryl group having 6 to 18 carbon atoms. In addition, it is preferred that the heterocyclic group represented by Ra and Rb is a condensed ring structure, a condensed ring structure of combination of rings selected from a furane ring, a thiophene ring, a cellenophene ring, a sylol ring, a pyridine ring, pyrazine ring, a pyrimidine ring, an oxazole ring, a thiazole ring, a triazole ring, an oxadiazole ring, and a thiadiazole ring (the rings may be the same as each other), and a quinoline ring, an isoquinoline ring, a benzothiophene ring, a dibenzothiophene ring, a thienothiophene ring, a bithienobenzene ring, and a bithienothiophene ring.

The arylene group and the aryl group represented by D₁, Ra and Rb are preferably a condensed ring structure, and more preferably a condensed ring structure including a benzene ring, and a naphthalene ring, an anthracene ring, a pyrene ring, and a phenanthrene ring may be cited, more preferably a benzene ring, a naphthalene ring or an anthracene ring, and further preferably a benzene ring or a naphthalene ring.

Examples of substituent W include a halogen atom, an alkyl group (including a cycloalkyl group, a bicycloalkyl group, and a tricycloalkyl group), an alkenyl group (including a cycloalkenyl group and a bicycloalkenyl group), an alkynyl group, an aryl group, a heterocyclic group (may also be called a hetero ring group), a cyano group, a hydroxy group, a nitro group, a carboxy group, an alkoxy group, an aryloxy group, a silyloxy group, a heterocyclic oxy group, an acyloxy group, a carbamoyloxy group, an alkoxycarbonyl group, an aryloxycarbonyl group, an amino group (including an anylino group), an ammonio group, an acylamino group, an aminocarbonylamino group, an alkoxycarbonylamino group, an aryloxycarbonylamino group, a sulfamoylamino group, an alkyl and arylsulfonylamino group, a mercapto group, an alkylthio group, an arylthio group, a heterocyclic thio group, a sulfamoyl group, a sulfo group, an alkyl and arylsulfinyl group, an alkyl and arylsulfonyl group, an acyl group, an aryloxycarbonyl group, an alkoxycarbonyl group, a carbamoyl group, an aryl and heterocyclic azo group, an imide group, a phosphino group, a phosphinyl group, a phosphinyloxy group, a phosphinylamino group, a phosphono group, a silyl group, a hydrazino group, a ureide group, a boronic acid group (—B(OH)₂), a phosphate group (—OPO(OPO(OH)₂), a sulfate group (—OSO₃H), and other known substituents.

In a case where Ra and Rb represent substituents (preferably alkyl groups or alkenyl groups), the substituents may be bonded to a hydrogen atom or a substituent of an aromatic ring (preferably benzene ring) skeleton of aryl group in which —NRa(Rb) is substituted to form a ring (preferably a six membered ring).

The substituents of Ra and Rb may bond to each other to form a ring (preferably a 5-membered or 6-membered ring and more preferably a 6-membered ring), and each of Ra and Rb may be bonded to a substituent in L (representing any one of L₁, L₂, and L₃) to form a ring (preferably a five membered or six membered ring and more preferably a six membered ring).

The compound represented by the general formula (1) is a compound described in Japanese Unexamined Patent Publication No. 2000-297068, and a compound that is not described in Japanese Unexamined Patent Publication No. 2000-297068 may be manufactured based on a synthesis method disclosed therein.

The compound represented by the general formula (1) is preferably a compound represented a general formula (2) below.

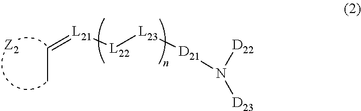

(In the general formula (2), Z₂, L₂₁, L₂₂, L₂₃, and n are synonymous with Z₁, L₁, L₂, L₃ and n of the general formula (1), and preferable examples thereof are the same. D₂₁ represents a substituted or unsubstituted arylene group. Each of D₂₂ and D₂₃ independently represents a substituted or unsubstituted aryl group or a substituted or unsubstituted heterocyclic group.) The arylene group represented by D₂₁ is synonymous with the arylene ring group represented by D₁ and preferable examples thereof are the same.

The aryl groups represent by D₂₂ and D₂₃, each independently is synonymous with the heterocyclic group represented by Ra and Rb, and preferable examples thereof are the same.

Specific preferable examples of compounds represented by the general formula (1) will be described using a general formula (3) below, but the present disclosure is not limited to these.

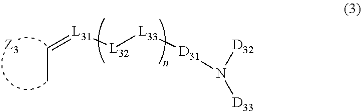

(In the formula (3), Z₃ represents any one of A-1 to A-12 shown below. L₃₁ represents methylene and n represents 0. D₃₁ represents any one of B-1 to B-9, and D₃₂ and D₃₃ represent any one of C-1 to C-16.) For Z₃, A-2 is preferable, D₃₂ and D₃₃ are preferably selected from C-1, C-2, C-15, and C-16, and D₃₁ is preferably B-1 or B-9.

### In The Table, [*] Indicates The Binding Position

| | |
|---|---|
| 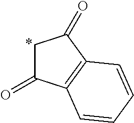 [SMILES: O=C1CC(=O)c2ccccc21] | A-1 |
| 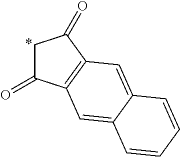 [SMILES: O=C1CC(=O)c2cc3ccccc3cc21] | A-2 |
| 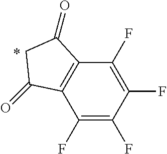 [SMILES: O=C1CC(=O)c2c(F)c(F)c(F)c(F)c21] | A-3 |
| 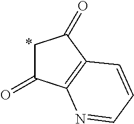 [SMILES: O=C1CC(=O)c2ncccc21] | A-4 |
| 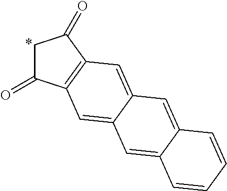 [SMILES: O=C1CC(=O)c2cc3cc4ccccc4cc3cc21] | A-5 |
| 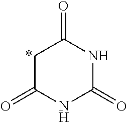 | A-6 |
| 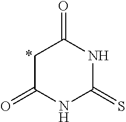 | A-7 |
| 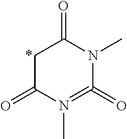 | A-8 |
| 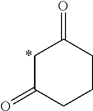 | A-9 |
| 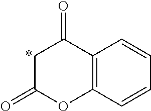 [SMILES: O=C1CC(=O)c2ccccc2O1] | A-10 |
| 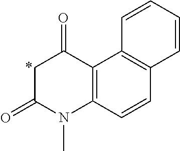 [SMILES: CN1C(=O)CC(=O)c2c1ccc1ccccc21] | A-11 |
| 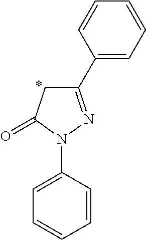 [SMILES: O=C1CC(c2ccccc2)=NN1c1ccccc1] | A-12 |
| 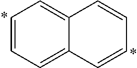 | B-1 |
| 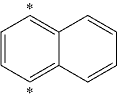 | B-2 |
| 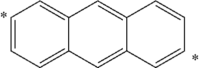 [SMILES: c1ccc2cc3ccccc3cc2c1] | B-3 |
| 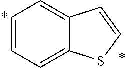 | B-4 |
| 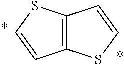 | B-5 |
| 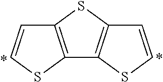 [SMILES: c1cc2sc3ccsc3c2s1] | B-6 |
| 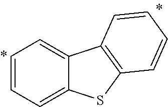 [SMILES: c1ccc2c(c1)sc1ccccc12] | B-7 |
| 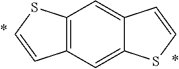 [SMILES: c1cc2cc3sccc3cc2s1] | B-8 |
| 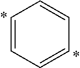 | B-9 |
| 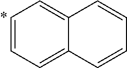 | C-1 |
| 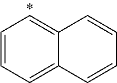 | C-2 |
| 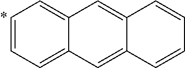 [SMILES: c1ccc2cc3ccccc3cc2c1] | C-3 |
| 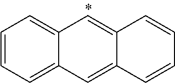 [SMILES: c1ccc2cc3ccccc3cc2c1] | C-4 |
| 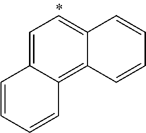 [SMILES: c1ccc2c(c1)ccc1ccccc12] | C-5 |
| 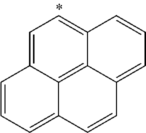 [SMILES: c1cc2ccc3cccc4ccc(c1)c2c34] | C-6 |
| 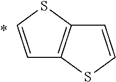 | C-7 |
| 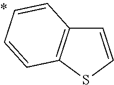 | C-8 |
| 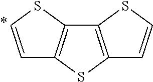 [SMILES: c1cc2sc3ccsc3c2s1] | C-9 |
| 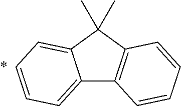 | C-10 |
| 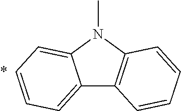 | C-11 |
| 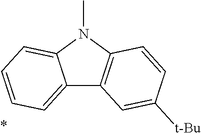 [SMILES: Cn1c2ccccc2c2cc(C(C)(C)C)ccc21] | C-12 |
| 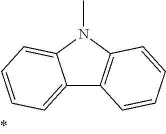 | C-13 |
| 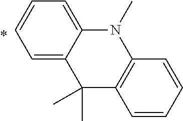 [SMILES: CN1c2ccccc2C(C)(C)c2ccccc21] | C-14 |
| 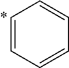 | C-15 |
| 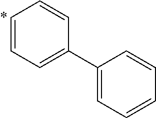 [SMILES: c1ccc(-c2ccccc2)cc1] | C-16 |

Examples of particularly preferable p-type organic semiconductors include a dye and a material not having five or more condensed ring structures (a material having 0 to 4 condensed ring structures and preferably 1 to 3 condensed ring structures). The use of a pigment-based p-type material generally used in an organic thin film solar cells tends to cause dark current to increase at the p-n interface and optical response to be delayed by the traps at crystal grain boundaries. As such, it is difficult to use the pigment-based p-type material for an imaging device. Accordingly, a dye-based p-type material which is less likely to crystallize or a material not having five or more condensed ring structures may be preferably used for an imaging device.

Further preferable examples of the compounds represented by the general formula (1) include the following combinations of substituents, linking groups, and partial structures in the general formula (3), but the present disclosure is not limited to these.

| COMPOUND | 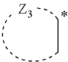 | L₃₁ | n | D₃₁ | D₃₂ | D₃₃ |
|---|---|---|---|---|---|---|
| 1 | A-1 | CH | 0 | B-9 | C-1 | C-1 |
| 2 | A-2 | CH | 0 | B-1 | C-1 | C-1 |
| 3 | A-3 | CH | 0 | B-9 | C-15 | C-15 |
| 4 | A-4 | CH | 0 | B-9 | C-15 | C-15 |
| 5 | A-5 | CH | 0 | B-9 | C-15 | C-15 |
| 6 | A-10 | CH | 0 | B-9 | C-15 | C-15 |
| 7 | A-11 | CH | 0 | B-9 | C-15 | C-15 |
| 8 | A-6 | CH | 0 | B-1 | C-15 | C-15 |
| 9 | A-7 | CH | 0 | B-1 | C-15 | C-15 |
| 10 | A-8 | CH | 0 | B-1 | C-15 | C-15 |
| 11 | A-9 | CH | 0 | B-1 | C-15 | C-15 |
| 12 | A-12 | CH | 0 | B-1 | C-15 | C-15 |
| 13 | A-2 | CH | 0 | B-2 | C-15 | C-15 |
| 14 | A-2 | CH | 0 | B-3 | C-15 | C-15 |
| 15 | A-2 | CH | 0 | B-9 | C-15 | C-15 |
| 16 | A-2 | CH | 0 | B-9 | C-16 | C-16 |
| 17 | A-1 | CH | 0 | B-9 | C-16 | C-16 |
| 18 | A-2 | CH | 0 | B-9 | C-1 | C-1 |
| 19 | A-2 | CH | 0 | B-1 | C-1 | C-2 |
| 20 | A-2 | CH | 0 | B-1 | C-1 | C-15 |
| 22 | A-2 | CH | 0 | B-1 | C-1 | C-3 |
| 23 | A-2 | CH | 0 | B-9 | C-15 | C-4 |
| 24 | A-2 | CH | 0 | B-9 | C-15 | C-5 |
| 25 | A-2 | CH | 0 | B-9 | C-15 | C-6 |
| 26 | A-2 | CH | 0 | B-9 | C-7 | C-7 |
| 27 | A-2 | CH | 0 | B-9 | C-8 | C-8 |
| 28 | A-2 | CH | 0 | B-1 | C-10 | C-10 |
| 29 | A-2 | CH | 0 | B-9 | C-11 | C-11 |
| 30 | A-2 | CH | 0 | B-9 | C-12 | C-12 |
| 31 | A-2 | CH | 0 | B-4 | C-15 | C-15 |
| 32 | A-2 | CH | 0 | B-5 | C-15 | C-15 |
| 33 | A-2 | CH | 0 | B-6 | C-15 | C-15 |
| 34 | A-2 | CH | 0 | B-7 | C-15 | C-15 |
| 35 | A-2 | CH | 0 | B-8 | C-15 | C-15 |

Here, A-1 to A-12, B-1 to B-9, and C-1 to C-16 are synonymous to those already described.

Particularly preferable examples of compounds represented by the general formula (1) include the following but the present disclosure is not limited to these.

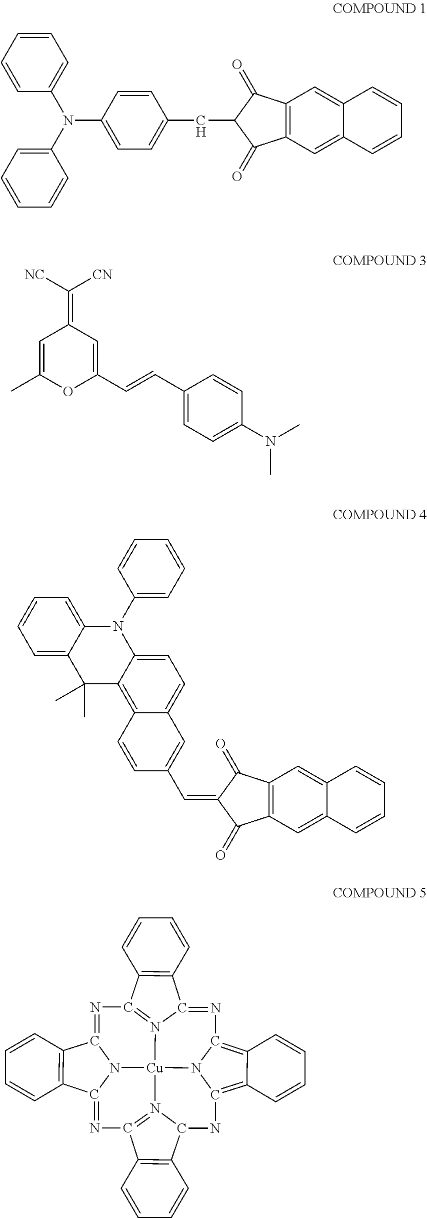

The photoelectric conversion layer 32 is a non-emissive layer unlike an organic EL emission layer (layer that converts an electrical signal to light). The “non-emissive layer” refers to a layer having a luminescent quantum efficiency less than or equal to 1%, preferably less than or equal to 0.5%, and more preferably less than or equal to 0.1% in the visible light region (wavelengths of 400 nm to 730 nm). In the photoelectric conversion layer 32, a luminescent quantum efficiency exceeding 1% is undesirable, because when the photoelectric conversion layer is applied to a sensor or an imaging device, it affects sensing performance or imaging performance.

### Electron Blocking Layer

The electron blocking layer 31 is a layer for suppressing injection of electrons from the hole collecting electrode 20 to the photoelectric conversion layer 32. The layer may be formed of an organic material single film or a mixed film of a plurality of different organic materials or inorganic materials.

The electron blocking layer 31 may be formed of a plurality of layers. This causes an interface to be created between each layer constituting the electron blocking layer 31 and discontinuity occurs in the intermediate level present in each layer. As a result, charge transfer via the intermediate level and the like becomes difficult to occur so that the electron blocking effect is increased. If each layer constituting the electron blocking layer 31 is made of the same material, however, the intermediate level presents in each layer may possible be exactly the same, it is preferable that a different material is used for each layer in order to enhance the electron blocking efficiency.

The electron blocking layer 31 is preferably made of a material having a high barrier against electron injection from the hole collecting electrode 20 and high hole transporting properties. As for the electron injection barrier, the electron affinity of the electron blocking layer is smaller than the work function of the adjacent electrode by greater than or equal to 1 eV, more preferably by greater than or equal to 1.3 eV, and particularly preferably by greater than or equal to 1.5 eV.

The electron blocking layer 31 is preferably greater than or equal to 20 nm, more preferably greater than or equal to 40 nm in order to sufficiently inhibit the contact between the hole collecting electrode 20 and the photoelectric conversion layer 32 and to avoid influence of defects or foreign particles present on the surface of the hole collecting electrode 20.

An electron donating organic material may be used for the electron blocking layer 31. More specifically, low molecular weight materials include aromatic diamine compounds, such as N, N′-bis (3-methylphenyl)-(1,1′-biphenyl)-4,4′-diamine (TPD), 4,4′-bis [N-(naphthyl)-N-phenyl-amino] biphenyl (α-NPD), and the like, porphyrin compounds, such as, oxazole, oxadiazole, triazole, imidazole, imidazolone, stilbene derivatives, pyrazoline derivatives, tetrahydroimidazole, polyarylalkane, butadiene, 4,4′, 4″-tris(N-(3-methylphenyl) N-phenylamino) triphenylamine (m-MTDATA), porphine, tetraphenylporphine copper, phthalocyanine, copper phthalocyanine, titanium phthalocyanine oxide, and the like, triazole derivatives, oxadiazole derivatives, imidazole derivatives, polyarylalkane derivatives, pyrazoline derivatives, pyrazolone derivatives, phenylenediamine derivatives, arylamine derivatives, fluorene derivatives, amino-substituted chalcone derivatives, oxazole derivatives, styryl anthracene derivatives, fluorenone derivatives, hydrazone derivatives, silazane derivatives, and the like, while polymeric materials include polymers, such as phenylene vinylene, fluorene, carbazole, indole, pyrene, pyrrole, picoline, thiophene, acetylene, diacetylene, and the like, and their derivatives. Even a non-electron donating compound may be used as long as it has a sufficient hole transporting property. More specifically, for example, the compounds described in Japanese Unexamined Patent Publication No. 2008-072090 and the like may preferably be used.

An example of a preferable compound for the electron blocking layer 31 is shown below.

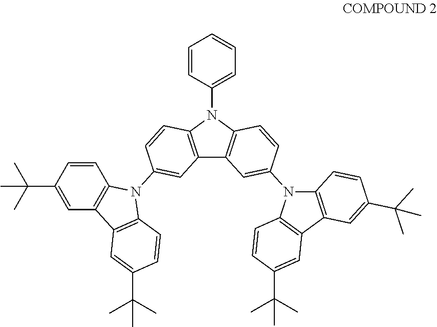 [SMILES: CC(C)(C)c1ccc2c(c1)c1cc(C(C)(C)C)ccc1n2-c1ccc2c(c1)c1cc(-n3c4ccc(C(C)(C)C)cc4c4cc(C(C)(C)C)ccc43)ccc1n2-c1ccccc1]

Inorganic materials may also be used for the electron blocking layer 31. As inorganic materials generally have a higher dielectric constant than organic materials, if used for the electron blocking layer 31, more voltage is applied to the photoelectric conversion layer 32 and the photoelectric conversion efficiency (sensitivity) may be improved. The materials that may be used for the electron blocking layer 31 include calcium oxide, chromium oxide, copper chromium oxide, manganese oxide, cobalt oxide, nickel oxide, copper oxide, copper gallium oxide, copper strontium oxide, niobium oxide, molybdenum oxide, copper indium oxide, silver indium oxide, iridium oxide, and the like.

If the electron blocking layer 31 is a single layer, the single layer may be made of an inorganic material and if it is formed of a plurality of layers, one or two or more layers may be formed of inorganic materials.

### Hole Blocking Layer

In the photoelectric conversion element 1, the hole blocking layer 33 is a layer that suppresses hole injection from the electron collecting electrode 40 when the external voltage is applied, and has a function to suppress film forming damage by protecting the photoelectric conversion layer 32 when the layer to be formed thereon (electron collecting electrode 40 in the present embodiment) is formed.

For the hole blocking layer, electron accepting materials may be used. There is not any specific restriction on the electron accepting materials, and oxadiazole derivatives, such as 1,3-bis (4-tert-butylphenyl-1,3,4-oxadiazolyl) phenylene (OXD-7), and the like, anthraquinodimethane derivatives, diphenyl quinone derivatives, bathocuproine, bathophenanthroline and derivatives of these, triazole compounds, tris (8-hydroxyquinolinato) aluminum complex, his (4-methyl-8-quinolinato) aluminum complex, distyrylarylene derivatives, Silole compounds, and the like may be used. Further, even a non-electron accepting compound may be used as long as it has a sufficient electron transporting property. More specifically, porphyrin-based compounds, styryl-based compounds, such as DCM (4-dicyano-2-methyl-6-(4-(dimethyl amino styryl))-4H pyran) and the like, and 4H pyran-based compounds may be used.

If a charge blocking layer formed of the hole blocking layer 33 and the electron blocking layer 31 is made too thick, problems that the supply voltage required to apply an appropriate electric field intensity to the photoelectric conversion layer is increased and a carrier transport process in the charge blocking layer gives adverse effects to the performance of the photoelectric conversion element may possibly occur. Therefore, the total film thickness of the hole blocking layer 33 and the electron blocking layer 31 is preferably designed to less than or equal to 300 nm. The total film thickness is more preferably less than or equal to 200 nm, and further preferably less than or equal to 100 nm

### Sealing Layer

The sealing layer 50 is a layer for preventing deterioration of the photoelectric conversion layer over a long period of storage/use by blocking the intrusion of factors that deteriorate the photoelectric conversion material, such as water molecules and oxygen molecules, after the photoelectric conversion element 1 or an imaging device 100, to be described later, is produced. The sealing layer 50 is also a layer for protecting the photoelectric conversion layer in the process of manufacturing the imaging device 100 after the sealing layer is formed by blocking the intrusion of factors, included in solution, plasma, and the like, that deteriorate the photoelectric conversion layer.

The sealing layer 50 is formed to cover the hole collecting electrode 20, the electron blocking layer 31, the photoelectric conversion layer 32, the hole blocking layer 33, and the electron collecting electrode 40.

As the incident light reaches the photoelectric conversion layer 32 through the sealing layer 50 in the photoelectric conversion element 1, the sealing layer needs to be sufficiently transparent to light having wavelengths to which the photoelectric conversion layer 32 has sensitivity to allow the light to be efficiently incident on the photoelectric conversion element 32. As for such sealing layer 50, ceramics, such as dense metal oxide, metal nitride, metal nitride which are impervious to water molecules, and diamond-like carbon (DLC) may be cited as examples, and conventionally, aluminum oxide, silicon oxide, silicon nitride, silicon nitride oxide, a layered film of these, and a layered film of these and an organic polymer, and the like have been used.

The sealing layer 50 may be formed of a thin film made of a single material, but by forming the sealing layer in a multilayer structure and giving a separate function to each layer, advantageous effects, such as stress relaxation of the entire sealing layer 50, inhibition of generation of defects, including cracks and pinholes, due to dust during the manufacturing process, ease of optimization of material development, and the like can be expected. For example, the sealing layer 50 may be formed in a two-layer structure in which a “sealing auxiliary layer” is layered on a layer that performs the original purpose of preventing the intrusion of deterioration factors, such as water molecules, the sealing auxiliary layer being given a function which is difficult to be achieved by the layer that performs the original purpose. A three or more layer structure may be possible, but the number of layers is preferably as small as possible in view of cost.

There is not any specific restriction of the method of forming the sealing layer 50, and the sealing layer is preferably formed by a method that does not deteriorate, as much as possible, the performance and film quality of the layers already formed, such as the photoelectric conversion layer 32 and the like.

The performance of an organic photoelectric conversion material is significantly deteriorated by the presence of deterioration factors, such as water molecules and oxygen molecules. Therefore, it is necessary to cover and seal the entire photoelectric conversion layer by a dense metal oxide, a metal nitride oxide, or the like that does not allow the deterioration factors to intrude into the layer. Conventionally, aluminum oxide, silicon oxide, silicon nitride, silicon nitride oxide, a layered structure of these, and a layered structure of these and an organic polymer, and the like have been formed as sealing layers by various types of vacuum film forming techniques.

In the conventional sealing layers, however, a thin film growth is difficult on steps (due to shadows by the steps) formed by structures of the substrate surface, small defects of the substrate surface, particles adhered to the substrate surface, and the like, and the film thickness is significantly thin on the steps in comparison with a flat portion. Consequently, the step portions serve as the routes of the deterioration factors. In order to completely cover the steps with the sealing layer, it is necessary to make the entire sealing layer thick by performing the film forming with a thickness of 1 μm on the flat portion. The degree of vacuum during the formation of the sealing layer is preferably less than or equal to 1×1 0³ Pa and more preferably less than or equal to 5×10² Pa.

For an imaging device with a pixel size of less than 2 μm, in particular, about 1 μm, if the film thickness of the sealing layer 50 is large, the distance between the color filter and the photoelectric conversion layer is increased and incident light may diffract/diffuse within the sealing layer and color mixing may possibly occur. Therefore, in view of the application to an imaging device with a pixel size of about 1 μm, a sealing material/manufacturing method is required that does not deteriorate the device performance even when the film thickness of the sealing layer 50 is reduced.

An atomic layer deposition (ALD) method is one of the CVD methods and a technique of forming a thin film by alternately repeating adsorption/reaction of organometallic compound molecules, metal halide molecules, metal hydride molecules to the substrate surface and dissolution of unreacted groups contained therein. When reaching the substrate surface, the thin film material is in a low molecular state as described above, so that a thin film growth is possible only if there is a very small space into which the small molecules may intrude. Therefore, the atomic layer deposition method may completely cover a step portion (the thickness of the thin film grown on the step portion is the same as that grown on a flat portion) which has been difficult by conventional thin film forming methods, that is, it is very excellent in step coverage. Thus, the method can completely cover the steps formed by structures of the substrate surface, small defects of the substrate surface, particles adhered to the substrate surface, and the like, so that such steps do not serve as intrusion routes of the deterioration factors of the photoelectric conversion material. In a case where the sealing layer 50 is formed by the atomic layer deposition method, the required film thickness may be reduced more effectively than the conventional technology.

In a case where the sealing layer 50 is formed by the atomic layer deposition method, a material corresponding to the preferable ceramics for the sealing layer 50 described above may be selected as appropriate. But, as the photoelectric conversion layer of the present disclosure uses an organic photoelectric conversion material, the materials are limited to those that allow a thin film growth at a relatively low temperature that does not deteriorate the organic photoelectric conversion material. According to the atomic layer deposition method with the use of alkyl aluminum or aluminum halide as the material, a dense aluminum oxide thin film may be formed at a temperature lower than 200° C. that does not deteriorate the organic photoelectric conversion material. The use of trimethyl aluminum, in particular, is preferable, because it allows an aluminum oxide thin film to be formed at about 100° C. A suitable selection of a material from silicon oxides and titanium oxides is also preferable, because it allows a dense thin film to be formed at a temperature lower than 200° C. as in the aluminum oxides.

Preferably, the sealing layer has a thickness of greater than or equal to 10 nm in order to sufficiently prevent intrusion of the factors, such as water molecules and the like, that deteriorate the photoelectric conversion material. In an imaging device, if the film thickness of the sealing layer is large, the incident light may diffract or diffuse within the sealing layer and color mixing may occur. Preferably, the thickness of the sealing layer is less than or equal to 200 nm.

The thin film formed by the atomic layer deposition method has incomparably good quality formed at a low temperature from the view point of step coverage and denseness. But, the physical properties of the thin film material may be deteriorated by a chemical used in a photolithography process. For example, as the aluminum oxide thin film formed by the atomic layer deposition method is amorphous, the surface may be eroded by alkali solutions, such as a developing solution and a peeling solution.

Further, thin films formed by CVD methods, such as the atomic layer deposition method, very often have a very large internal tensile stress and the thin film itself may have deterioration of cracking by a process in which heating and cooling are repeated intermittently, as in the semiconductor manufacturing process, and the storage/use over a long period of time under a high temperature/high humidity environment.

Therefore, if the sealing layer 50 formed by the atomic layer deposition method is used, a sealing auxiliary layer which is excellent in chemical resistance and capable of cancelling the internal stress of the sealing layer 50 is preferably formed.

An example of such sealing auxiliary layer may be a layer that includes any one of the ceramics, such as metal oxide, metal nitride, and metal nitride oxide excellent in chemical resistance formed, for example, by a physical vapor deposition (PVD) film forming method Films of ceramics formed by the PVD methods, such as the sputtering method, often have a large compression stress and may cancel the tensile stress of the sealing layer 50 formed by the atomic layer deposition method.

In the photoelectric conversion element 1, the external electric field applied between the hole collecting electrode 20 and the electron collecting electrode 40 is 1 V/cm to 1×10⁷ V/cm to obtain excellent properties in photoelectric conversion efficiency (sensitivity), dark current, and optical response speed. The external electric field is a value of the voltage externally applied between a pair of electrodes divided by the distance between the electrodes.

In the photoelectric conversion element 1, the light receiving layer 30 is formed by the electron blocking layer 31, the photoelectric conversion layer 32, and the hole blocking layer 33. The photoelectric conversion element 1 according to the present embodiment includes the hole blocking layer 33, but the advantageous effects of the present disclosure may be obtained regardless of whether or not the hole blocking layer 33 is provided, since the hole blocking layer 33 does not contribute to the flow of holes.

As described above, the photoelectric conversion element 1 includes the photoelectric conversion layer 32 formed of the first photoelectric conversion layer 32b and the second photoelectric conversion layer 32a, in which the second photoelectric conversion layer 32a is formed on the surface of the first photoelectric conversion layer 32b on the electron collecting electrode 20 side and is composed such that the average value of the mixing ratio of the n-type organic semiconductor to the p-type organic semiconductor is higher than the average value in the photoelectric conversion layer 32 formed of the first photoelectric conversion layer 32b and the second photoelectric conversion layer 32a. According to such composition, the decrease in mobility in the photoelectric conversion layer due to the presence of a single composition film of the p-type organic semiconductor or an area of a large composition of the p-type organic semiconductor at an end portion on the hole collecting electrode side, and recombination near the end portion may be suppressed. Therefore, the organic photoelectric conversion element of the present disclosure is excellent in response speed, carrier transportability (sensitivity), and heat resistance.

### Imaging Device

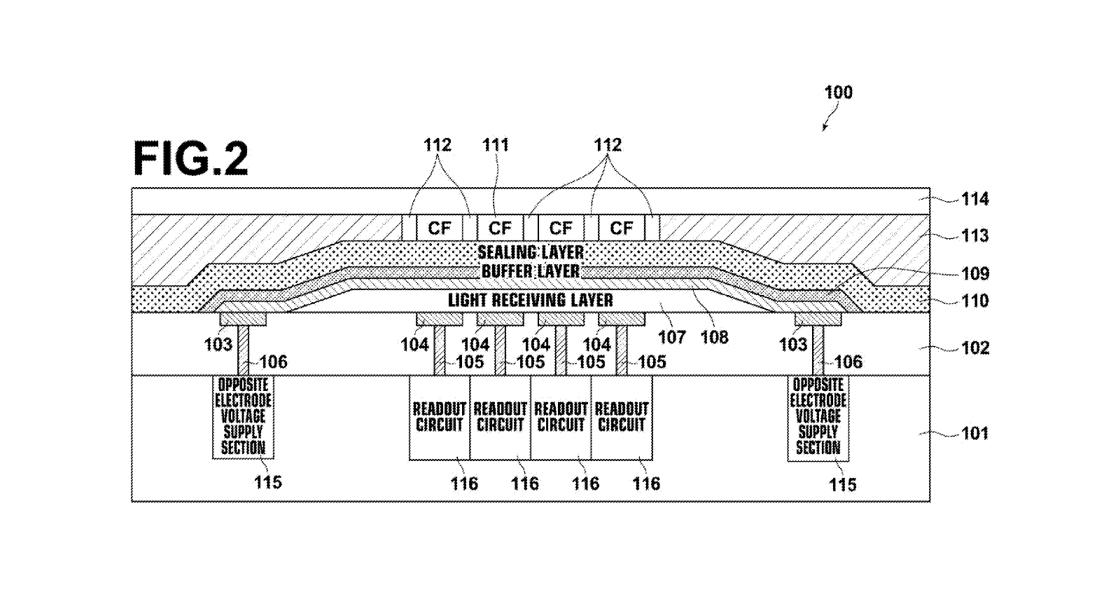

Next, a structure of an imaging device 100 equipped with the photoelectric conversion element 1 will be described with reference to FIG. 2. FIG. 2 is a schematic cross-sectional view of an imaging device for explaining one embodiment of the present disclosure. The imaging device is used by being mounted on imaging apparatuses, such as digital cameras, digital video cameras, and the like, electronic endoscopes, imaging modules of cell phones and the like, and others.

The imaging device 100 includes a plurality of organic photoelectric conversion elements 1 having a structure shown in FIG. 1 and a circuit substrate in which is formed a readout circuit for reading out a signal according to a charge generated in the photoelectric conversion layer of each organic photoelectric conversion element, and has a structure in which the plurality of organic photoelectric conversion elements 1 is disposed one- or two-dimensionally on the same plane above the circuit substrate.

The imaging device 100 includes a substrate 101, an insulating layer 102, a connection electrode 103, a pixel electrode 104, a connection section 105, a connection section 106, a light receiving layer 107, an opposite electrode 108, a buffer layer 109, a sealing layer 110, a color filter (CF) 111, a partition wall 112, a light shielding layer 113, a protection layer 114, an opposite electrode voltage supply section 115, and a readout circuit 116.

The pixel electrode 104 has the same function as that of the hole collecting electrode 20 of the organic photoelectric conversion element 1 illustrated in FIG. 1. The opposite electrode 108 has the same function as that of the electron collecting electrode 40 of the organic photoelectric conversion element 1 illustrated in FIG. 1. The light receiving layer 107 has the same structure as that of the light receiving layer 30 provided between the hole collecting electrode 20 and the electron collecting electrode 40 of the organic photoelectric conversion element 1 illustrated in FIG. 1. The sealing layer 110 has the same function as that of the sealing layer 50 of the organic photoelectric conversion element 1 illustrated in FIG. 1. A pixel electrode 104, a portion of the opposite electrode 108 facing the pixel electrode 104, the light receiving layer 107 sandwiched by these electrodes, and portions of the buffer layer 109 and the sealing layer 110 constitute an organic photoelectric conversion element.

The substrate 101 is a glass substrate or a semiconductor substrate, such as Si or the like. The insulating layer 102 is formed on the substrate 101. A plurality of pixel electrodes 104 and a plurality of connection electrodes 103 are formed on the surface of the insulating layer 102.

The light receiving layer 107 is a layer which is provided over the plurality of pixel electrodes 104 to cover them and common to all the organic photoelectric conversion elements.

The opposite electrode 108 is one electrode which is provided on the light receiving layer 107 and common to all of the organic photoelectric conversion elements.

The opposite electrode 108 is formed over to the connection electrodes 103 disposed outside of the light receiving layer 107 and electrically connected to the connection electrodes 103.

The connection section 106 is buried in the insulating layer 102 and is a plug or the like for electrically connecting the connection electrode 103 and the opposite electrode voltage supply section 115. The opposite electrode voltage supply section 115 is formed in the substrate 101 and applies a predetermined voltage to the opposite electrode 108. In a case where the voltage to be applied to the opposite electrode 108 is higher than the power source voltage of the imaging device, the predetermined voltage described above is supplied by boosting the power source voltage with a booster circuit, such as a charge pump or the like.

The readout circuit 116 is provided in the substrate 101 correspondingly to each of a plurality of pixel electrodes 104, and is a circuit for reading out a signal according to a change collected by the corresponding pixel electrode 104. The readout circuit 116 is formed of, for example, a CCD circuit, a MOS circuit, a TFT circuit or the like, and shielded by a light shielding layer, not shown, disposed in the insulating layer 102. The readout circuit 116 is electrically connected to the corresponding pixel electrode 104 via the connection section 105.

The buffer layer 109 is formed on the opposite electrode 108 to cover the opposite electrode 108. The sealing layer 110 is formed on the buffer layer 109 to cover the buffer layer 109. The color filter 111 is formed at a position on the sealing layer 110 corresponding to each pixel electrode 104. The partition wall 112 is provided between the color filters 111 to improve light transmission rate of the color filters 111.

The light shielding layer 113 is formed on an area of the sealing layer 110 other than the areas where color filters 111 and partition walls 112 are formed to prevent light from entering a portion of the light receiving layer 107 other than the effective pixel areas. The protection layer 114 is formed on the color filters 111, the partition walls 112, and light shielding layer 113 to protect the entire imaging device 100.

In the imaging device 100 structured in the manner described above, when light is incident, the light enters in the light receiving layer 107 and charges are generated therein. Holes of the generated charges are collected by the pixel electrode 104 and a voltage signal according to the collected amount is outputted outside the imaging device 100 by the readout circuit 116.

The manufacturing method of the imaging device 100 is as follows. The connection sections 105, 106, a plurality of connection electrodes 103, a plurality of pixel electrodes 104, and the insulating layer 102 are formed on the circuit substrate in which opposite electrode voltage supply sections 115 and readout circuits 116 are formed. The plurality of pixel electrodes 104 is disposed, for example, in a square grid pattern on the surface of the insulating layer 102.

Then, the light receiving layer 107, the opposite electrode 108, the buffer layer 109, and the sealing layer 110 are formed in order on the plurality of pixel electrodes 104. The methods of forming the light receiving layer 107, the opposite electrode 108, and sealing layer 110 are as describe in the foregoing explanation of the photoelectric conversion element 1. The buffer layer 109 is formed, for example, by a vacuum resistance heating evaporation method. Next, the color filters 111, the partition walls 112, and the light shielding layer 113, the protection layer 114 are formed to complete the manufacture of the imaging device 100.

### EXAMPLES

### Example 1

A CMOS substrate which includes a Si substrate having a pattern formed TiN electrode thereon was provided, and the CMOS substrate was set to a substrate holder in an organic deposition chamber and the pressure in the deposition chamber was reduced to less than or equal to 1.0×10⁻⁴ Pa. Thereafter, while rotating the substrate holder, the compound 2 was deposited at a deposition speed of 1.0 to 1.2 Å/sec to a thickness of 1000 Å as the electron blocking layer. Next, the second photoelectric conversion layer was formed by depositing the compound 1 and C₆₀, each at a deposition speed of 1.2 to 1.4 Å/sec and 5.1 to 5.3 Å/sec to a thickness of 10 Å. Then, the first photoelectric conversion layer was formed by depositing the compound 1 and C₆₀, each at a deposition speed of 1.2 to 1.4 Å/sec and 3.8 to 4.0 Å/sec, to a thickness of 3990 Å.

Next, after moving to a sputtering chamber, ITO was sputtered on the first photoelectric conversion layer, as the opposite electrode, by RF magnetron sputtering to a thickness of 100 Å. Then, after moving to an atomic layer deposition (ALD) chamber, Al₂O₃ film was formed as the protection film by ALD method to a thickness of 2000 Å. Then, after moving to the sputtering chamber, a SiON film was formed by planer type sputtering to a thickness of 1000 Å, whereby an imaging device was produced.

### Example 2

An imaging device was produced in the same manner as that of Example 1 other than that the compound 1 and C₆₀ were deposited, each at a deposition speed of 1.2 to 1.4 Å/sec and 6.4 to 6.6 Å/sec, to a thickness of 10 Å.

### Example 3

An imaging device was produced in the same manner as that of Example 1 other than that the compound 1 and C₆₀ were deposited, each at a deposition speed of 1.2 to 1.4 Å/sec and 7.7 to 7.9 Å/sec, to a thickness of 10 Å.

### Example 4

An imaging device was produced in the same manner as that of Example 1 other than that only C₆₀ was deposited, instead of the compound 1 and C₆₀, at a deposition speed of 2.5 to 2.8 Å/sec to a thickness of 10 Å.

### Example 5

An imaging device was produced in the same manner as that of Example 1 other than that the compound 1 and C₆₀ were deposited, each at a deposition speed of 1.2 to 1.4 Å/sec and 5.1 to 5.3 Å/sec, to a thickness of 30 Å.

### Example 6

An imaging device was produced in the same manner as that of Example 1 other than that the compound 1 and C₆₀ were deposited, each at a deposition speed of 1.2 to 1.4 Å/sec and 5.1 to 5.3 Å/sec, to a thickness of 50 Å.

### Example 7

An imaging device was produced in the same manner as that of Example 1 other than that the compound 3 and C₆₀ were deposited, each at a deposition speed of 1.2 to 1.4 Å/sec and 5.1 to 5.3 Å/sec, to a thickness of 30 Å.

### Example 8

An imaging device was produced in the same manner as that of Example 1 other than that the compound 4 and C₆₀ were deposited, each at a deposition speed of 1.2 to 1.4 Å/sec and 5.1 to 5.3 Å/sec, to a thickness of 30 Å.

### Example 9

An imaging device was produced in the same manner as that of Example 1 other than that the compound 5 and C₆₀ were deposited, each at a deposition speed of 1.2 to 1.4 Å/sec and 5.1 to 5.3 Å/sec, to a thickness of 30 Å.

### Comparative Example 1

An imaging device was produced in the same manner as that of Example 1 other than that only the compound 1 was deposited, instead of the compound 1 and C₆₀, at a deposition speed of 1.2 to 1.4 Å/sec to a thickness of 10 Å.

### Comparative Example 2

An imaging device was produced in the same manner as that of Example 1 other than that the compound 1 and C₆₀ were deposited, each at a deposition speed of 1.2 to 1.4 Å/sec and 1.2 to 1.4 Å/sec, to a thickness of 10 Å.

### Comparative Example 3

An imaging device was produced in the same manner as that of Example 1 other than that the compound 1 and C₆₀ were deposited, each at a deposition speed of 1.2 to 1.4 Å/sec and 2.5 to 2.8 Å/sec, to a thickness of 10 Å.

### Comparative Example 4

An imaging device was produced in the same manner as that of Example 1 other than that the compound 1 and C₆₀ were deposited, each at a deposition speed of 1.2 to 1.4 Å/sec and 3.8 to 4.0 Å/sec, to a thickness of 10 Å.

### Evaluations

The foregoing examples and comparative examples were evaluated for performance degradation through sensitivity measurements using an incident photon-to-current efficiency (IPCE) measurement apparatus, response speed measurements using a pulse generator, and dark current measurements by heat treatment at 220° C., the results of which are shown in Table 1. In Table 1, the sensitivities and response speeds are shown by the relative values when the photoelectric conversion efficiency is taken as 100. The dark current increase rate for each device is an increase rate after annealing with reference to the dark current value before annealing. Table 1 also shows the film thickness (average value) of the first photoelectric conversion layer and the average values of the mixing ratios between the n-type organic semiconductor and the p-type organic semiconductor in the first photoelectric conversion layer and the second photoelectric conversion layer in each example and comparative example. The mixing ratio is shown by the proportion of the n-type organic semiconductor to the p-type organic semiconductor.

As shown in Table 1, examples have sensitivities and response speeds which are about two times of those of Comparative Examples 1 to 3, demonstrating high effects of the present disclosure. Further, it was also confirmed that the dark current that serves as the index of heat resistance has improved largely by the present disclosure.

TABLE 1

| | | | | | Mixing Ratio between | Mixing Ratio between |
|---|---|---|---|---|---|---|
| | | | Dark Current | Film Thickness | n- and p-Type | n- and p-Type pH |
| | | | Increase | of First | Semiconductors | Semiconductors [n]/[p] |
| | | | Rate after Heat | Photoelectric | [n]/[p] in First | in Second |
| | sensitivity | Response | Treatment at | Conversion | Photoelectric Conversion | Photoelectric Conversion |
| | (%) | Speed (%) | 220° C. | Layer (Å) | Layer (%) | Layer (%) |
| Example 1 | 100 | 100 | 0 | 10 | 80 | 75 |
| Example 2 | 100 | 100 | 0 | 10 | 83 | 75 |
| Example 3 | 100 | 100 | 0 | 10 | 86 | 75 |
| Example 4 | 100 | 100 | 0 | 10 | 100 | 75 |
| Example 5 | 100 | 100 | 0 | 30 | 80 | 75 |
| Example 6 | 95 | 90 | 0 | 50 | 80 | 75 |
| Example 7 | 100 | 100 | 0 | 30 | 80 | 75 |
| Example 8 | 100 | 100 | 0 | 30 | 80 | 75 |
| Example 9 | 100 | 100 | 0 | 30 | 80 | 75 |
| Com- | 50 | 53 | 250 | 10 | 0 | 75 |
| parative | | | | | | |
| Example 1 | | | | | | |
| Com- | 50 | 55 | 240 | 10 | 50 | 75 |
| parative | | | | | | |
| Example 2 | | | | | | |
| Com- | 60 | 65 | 220 | 10 | 67 | 75 |
| parative | | | | | | |
| Example 3 | | | | | | |
| Com- | 100 | 100 | 120 | 10 | 75 | 75 |
| parative | | | | | | |
| Example 4 | | | | | | |

What is claimed is:

1. An organic photoelectric conversion element, comprising a light receiving layer which includes at least a photoelectric conversion layer sandwiched between a hole collecting electrode and an electron collecting electrode, wherein:
an electron blocking layer is provided between the hole collecting electrode and the electron collecting electrode;
the photoelectric conversion layer is formed of a first photoelectric conversion layer which is a bulk hetero layer of an n-type organic semiconductor and a p-type organic semiconductor, and a second photoelectric conversion layer formed in contact with the surface of the first photoelectric conversion layer on the hole collecting electrode side; and
the average value of the mixing ratio of the n-type organic semiconductor to the p-type organic semiconductor in the second organic semiconductor layer is higher than the average value in the photoelectric conversion layer formed of the first photoelectric conversion layer and the second photoelectric conversion layer.

2. The photoelectric conversion element of claim 1, wherein the thickness of the second photoelectric conversion layer is less than or equal to 0.75% of the thickness of the photoelectric conversion layer formed of the first photoelectric conversion layer and the second photoelectric conversion layer.

3. The photoelectric conversion element of claim 1, wherein the hole collecting electrode is a lower electrode.

4. The photoelectric conversion element of claim 1, wherein the n-type organic semiconductor includes a fullerene.

5. The photoelectric conversion element of claim 1, wherein the p-type organic semiconductor includes a compound represented by a general formula (1) below: 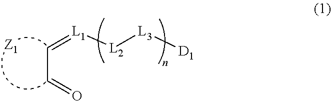
where, Z₁ represents a ring containing at least two carbon atoms and represents a fused ring containing at least one of five membered ring, a six membered ring, or five and six membered rings, L₁, L₂, and L₃ each independently represents an unsubstituted methine group or a substituted methine group, D₁ represents a group of atoms, and n represents an integer greater than or equal to 0.

6. An imaging device, comprising:
a plurality of the photoelectric conversion elements of claim 1; and
a circuit substrate in which is formed a signal readout circuit for reading out a signal according to a charge generated in the photoelectric conversion layer of each organic photoelectric conversion element.
